(19) United States
(12) Patent Application Publication
(10) Pub. No.: US 2018/0355469 A1
(43) Pub. Date: Dec. 13, 2018

(54) HARD COATING AND HARD COATING-COVERED MEMBER

(71) Applicant: Kabushiki Kaisha Kobe Seiko Sho (Kobe Steel, Ltd.), Kobe-shi, Hyogo (JP)

(72) Inventors: Kenji YAMAMOTO, Hyogo (JP); Hiroaki NII, Hyogo (JP); German FOX-RABINOVICH, Hamilton (CA)

(73) Assignee: Kabushiki Kaisha Kobe Seiko Sho (Kobe Steel, Ltd.), Kobe-shi, Hyogo (JP)

(21) Appl. No.: 15/571,287

(22) PCT Filed: Apr. 25, 2016
(86) PCT No.: PCT/JP2016/062930

§ 371 Date: Nov. 2, 2017

(30) Foreign Application Priority Data
May 12, 2015 (JP) 2015-097299

(51) Int. Cl. C23C 14/06; C23C 28/04; C23C 28/00

(52) U.S. Cl. CPC C23C 14/0664; C23C 28/42; C23C 28/044; C23C 28/042

(57) ABSTRACT

A hard film to be formed on a substrate satisfying the composition represented by formula (1):

TiₐCr_{b}Al_{c}Zr_{d}Lₑ(BₓC_{y}N_{z}),

wherein: L represented one or more elements of Si and Y; a, b, c, d, e, x, y, and z are atomic ratios of Ti, Cr, Al, Zr, L, B, C, and N, respectively; and the atomic ratios satisfy the following ranges: 0≤a≤0.30, 0.10≤b ≤0.30, 0.40≤c≤0.70, 0.03≤d≤0.20, 0≤e≤0.10, 0≤x≤0.15, 0≤y≤0.10, 0.80≤z≤1, a+b+c+d+e=1 and x+y+z=1.

### TECHNICAL FIELD

The present invention relates to a hard film and a hard film-coated member, and particularly to a hard film having excellent adhesion resistance and wear resistance and a hard film-coated member in which the hard film is formed on a substrate.

### BACKGROUND ART

A titanium-based metal such as pure titanium or a titanium alloy has properties such as high high-temperature strength and low thermal conductivity. Accordingly, when cutting is performed, for example, using the titanium-based metal as a material to be cut, heat generated during cutting is less likely to escape to a side of the material to be cut or a side of chips, and is liable to accumulate on a cutting edge of a cutting tool. As a result, the cutting edge temperature is liable to increase. Further, titanium is chemically active, so that titanium adhesion to the tool is liable to occur with an increase in the above-mentioned cutting edge temperature. The wear of the tool is easily progressed by this adhesion, and there is a problem that the wear resistance decreases, resulting in a shortened tool life. The adhesion of a metal such as the titanium-based metal is hereinafter sometimes simply referred to as “adhesion”.

In order to suppress the above-mentioned adhesion of the titanium-based metal during cutting, working has hitherto been generally performed by a wet process and at a low cutting rate. However, improvement in productivity is required, and to the cutting tool for the above-mentioned titanium-based metal, it is required that the above-mentioned adhesion can be suppressed without decreasing the cutting rate.

In order to satisfy the above-mentioned requirement, attempts have been made to suppress the adhesion by applying a coating onto the cutting edge of the cutting tool, thereby increasing the cutting rate. For example, as the above-mentioned coating, a film of a high-melting-point compound such as TiAlN has hitherto been proposed. Further, Patent Document 1 shows a surface-coated cutting tool for working a titanium alloy, which is characterized in that the tool is formed of a compound composed of Al, either one or both elements of Cr and V, and any one or more elements of nitrogen, carbon and oxygen. Furthermore, Patent Document 1 shows that when the above-mentioned compound contains V, oxide of V having a low melting point acts as a lubricant in a high-temperature environment during cutting, whereby an effect of suppressing adhesion of a material to be cut can be expected.

Patent Document 2 shows a cutting tool improved in properties suitable for cutting titanium and an alloy thereof, which comprises a substrate containing tungsten carbide and one coating of a coating selected from the group consisting of tungsten carbide and boron carbide and adhered to the above-mentioned substrate by a physical vapor-deposition process and a coating comprising boron carbide and adhered to the above-mentioned substrate by a chemical vapor-deposition process.

### PRIOR ART DOCUMENTS Patent Documents

Patent Document 1: JP-A-2005-262389

Patent Document 2: JP-A-9-216104

### SUMMARY OF THE INVENTION Problems that the Invention is to Solve

The above-mentioned problem of adhesion of the titanium-based metal to the tool may occur not only for the above-mentioned cutting tool, but also for a tool used for plastically working the titanium-based metal. The present invention has been made in view of these circumstances, and an object of the present invention is to provide a hard film which can more suppress adhesion of a component to be worked during work than a film of a conventionally used high-melting-point compound such as TiAlN to achieve satisfactory work such as cutting work or plastic work even when a material to be worked is a titanium-based metal, and a hard film-coated member such as a cutting tool or a tool for plastic work, in which the hard film is formed on a substrate. The property of suppressing the adhesion of the component to be worked during the work such as the cutting work or the plastic work is hereinafter sometimes referred to as “adhesion resistance”.

### Means for Solving the Problems

A hard film of the present invention which can solve the above-mentioned problems is a hard film to be formed on a substrate, satisfying a composition represented by the following formula (1).

TiₐCr_{b}Al_{c}Zr_{d}Lₑ(BₓC_{y}N_{z}) . . . (1)

In the above formula (1),

L is one kind or more of elements of Si and Y,

a, b, c, d, e, x, y, and z are atomic ratios of Ti, Cr, Al, Zr, L, B, C, and N, respectively, and

the atomic ratios satisfy the following ranges:

0≤a≤0.30, 0.10≤b≤0.30, 0.40≤c≤0.70, 0.03≤d≤0.20, 0≤e≤0.10, 0≤x≤0.15, 0≤y≤0.10, 0.80≤z≤1, a+b+c+d+e=1, and x+y+z=1.

Another hard film of the present invention which can solve the above-mentioned problems is a hard film to be formed on a substrate, including: a film(s) Q satisfying a composition represented by the following formula (2) and having a film thickness of 1.0 nm or more and 50 nm or less; and a film(s) R satisfying a composition represented by the following formula (3) and having a film thickness of 1.0 nm or more and 50 nm or less, in which the film(s) Q and the film(s) R are alternately laminated.

Film Q: TiₐCr_{b}Al_{c}Lₑ(BₓC_{y}N_{z}) . . . (2)

In the above formula (2),

L is one kind or more of elements of Si and Y,

a, b, c, e, x, y, and z are atomic ratios of Ti, Cr, Al, L, B, C, and N, respectively, and

the atomic ratios satisfy the following ranges:

0≤a≤0.30, 0.10≤b≤0.30, 0.40≤c≤0.70, 0≤e≤0.10, 0≤x≤0.15, 0≤y≤0.10, 0.80≤z≤1, a+b+c+e=1, and x+y+z=1.

Film R: Zr(BₛCₜNᵤ) . . . (3)

In the above formula (3),

s, t and u are atomic ratios of B, C and N, respectively, and the atomic ratios satisfy the following ranges:

0≤s≤0.15, 0≤t≤0.10, 0.80≤u≤1, and s+t+u=1.

The present invention also includes a hard film-coated member including a substrate and the above-mentioned hard film formed on the substrate. The hard film-coated members include a cutting tool used for cutting a pure titanium or a titanium alloy and a tool for plastic work used for plastically working a pure titanium or a titanium alloy.

### Advantageous Effects of the Invention

According to the present invention, there can be provided a hard film which suppresses adhesion of a component to be worked during cutting work or plastic work and can achieve satisfactory cutting or plastic work, even when a material to be worked is a titanium-based metal, and a hard film-coated member in which the hard film is formed on a substrate.

### MODE FOR CARRYING OUT THE INVENTION

As described above, during working a metal material, particularly during working pure titanium or a titanium alloy, an easy increase in temperature of a cutting edge during cutting because of its low thermal conductivity and the property of a titanium-based metal of being chemically active are combined to cause easy occurrence of adhesion on a wear surface of a tool for work such as a cutting tool or a tool for plastic work. In wear of the tool for working the titanium-based metal, specifically, in wear of a film on a surface of the tool, so-called adhesion wear which progresses from an adhesion part of the above-mentioned titanium-based metal as a starting point is dominant. Accordingly, in order to prolong the life of the above-mentioned tool for work, it is not enough that the film coated on the tool is excellent in heat resistance, and it becomes necessary to be also excellent in adhesion resistance on the wear surface.

Therefore, in order to obtain a hard film particularly excellent in adhesion resistance even when the material to be worked is the titanium-based metal, the present inventors have made intensive studies particularly on the composition of the hard film. As a result, when a specified amount of Zr is allowed to be contained in a film having high oxidation resistance, such as TiCrAl(BCN), CrAl(BCN), TiCrAl(Si/Y)(BCN), or CrAl(Si/Y)(BCN), to obtain a composition represented by the following formula (1), it has been found that the adhesion of the titanium-based metal can be reduced to sufficiently increase the life of the tool for work, in other words, that the hard film excellent in adhesion resistance and wear resistance is obtained. Zr described above is preferentially oxidized by frictional heat during cutting to form ZrO₂ as an extremely stable oxide. In addition, ZrO₂ has low reactivity with Ti, so that the adhesion of the titanium-based metal on the wear surface can be suppressed.

TiₐCr_{b}Al_{c}Zr_{d}Lₑ(BₓC_{y}N_{z}) . . . (1)

In the above formula (1),

L is one kind or more of elements of Si and Y,

a, b, c, d, e, x, y, and z are atomic ratios of Ti, Cr, Al, Zr, L, B, C, and N, respectively, and

the atomic ratios satisfy the following ranges:

0≤a≤0.30, 0.10≤b≤0.30, 0.40≤c≤0.70, 0.03≤d≤0.20, 0≤e≤0.10, 0≤x≤0.15, 0≤y≤0.10, 0.80≤z≤1, a+b+c+d+e=1, and x+y+z=1.

The Zr amount necessary for exerting the above-mentioned function and effect is 0.03 or more by the atomic ratio d to the metal elements, that is, Ti, Cr, Al, Zr, and L. The atomic ratio d of Zr is preferably 0.05 or more, and more preferably 0.10 or more. On the other hand, when Zr is excessively contained, the oxidation resistance of the film decreases. Accordingly, the atomic ratio d of Zr is 0.20 or less, and preferably 0.15 or less.

From the viewpoint of securing the oxidation resistance and the hardness of the film necessary during cutting and the like, the above-mentioned elements other than Zr, that is, Ti, Cr, Al, L, B, C, and N, are within the ranges of the above formula (1). The ranges of each of the elements are shown below, together with preferred ranges thereof.

First, the atomic ratio a of Ti to the metal elements is 0.30 or less. The atomic ratio a of Ti is preferably 0.25 or less, more preferably 0.20 or less, and still more preferably 0.10 or less. The atomic ratio a of Ti may be zero, but can be, for example, 0.05 or more, when Ti is allowed to be contained.

The atomic ratio b of Cr to the metal elements is 0.10 or more and 0.30 or less, preferably 0.25 or less, and more preferably 0.20 or less.

The atomic ratio c of Al to the metal elements is 0.40 or more, preferably 0.45 or more, and more preferably 0.50 or more. On the other hand, the upper limit of the atomic ratio c of Al is 0.70 or less, preferably 0.65 or less, and more preferably 0.60 or less.

The atomic ratio e of L, that is, one kind or more of elements of Si and Y, to the metal elements may be zero, but is preferably 0.03 or more. The upper limit of the above-mentioned atomic ratio e is 0.10 or less, preferably 0.08 or less, and more preferably 0.05 or less. The above-mentioned atomic ratio e means the total amount of Si and Y The same applies hereinafter. Si and Y may be used alone or may be used as a combination of two kinds thereof.

In the film of the present invention, the atomic ratio z of N to B, C and N is 0.80 or more and 1 or less. The atomic ratio z of N is preferably 0.85 or more, and more preferably 0.90 or more. As described above, the film of the present invention basically uses a nitride as a base. However, B or C may be added. The atomic ratio x of B may be zero, but can be, for example, 0.01 or more, and further 0.02 or more. However, from the viewpoint of securing the wear resistance, the atomic ratio x of B is 0.15 or less, preferably 0.10 or less, and more preferably 0.05 or less.

In addition, the adhesion is suppressed by adding C described above. The atomic ratio y of C may be zero, but can be, for example, 0.03 or more, for obtaining the adhesion suppressing effect. However, from the viewpoint of securing the wear resistance, the atomic ratio y of C is 0.10 or less, preferably 0.07 or less, and more preferably 0.05 or less.

Further, the present inventors have found that an effect similar to that of the film in which Zr is homogeneously dissolved in solid as represented by the above formula (1) is obtained also when films composed of TiCrAlL(BCN) represented by the following formula (2) and films composed of Zr(BCN) represented by the following formula (3) are alternately laminated. The ranges of each of the atomic ratios a, b, c, e, x, y, and z of Ti, Cr, Al, L, B, C, and N in the following formula (2) and the preferred upper and lower limit values thereof, and the ranges of each of the atomic ratios s, t and u of B, C and N in the following formula (3) and the preferred upper and lower limit values thereof are the same as those of the atomic ratios of Ti, Cr, Al, L, B, C, and N in the above formula (1).

Film Q: TiₐCr_{b}Al_{c}Lₑ(Bₓ,C_{y}N_{z}) . . . (2)

In the above formula (2),

L is one kind or more of elements of Si and Y,

a, b, c, e, x, y, and z are the atomic ratios of Ti, Cr, Al, L, B, C, and N, respectively, and

the atomic ratios satisfy the following ranges:

0≤a≤0.30, 0.10≤b≤0.30, 0.40≤c≤0.70, 0≤e≤0.10, 0≤x≤0.15, 0≤y≤0.10, 0.80≤z≤1, a+b+c+e=1, and x+y+z=1.

Film R: Zr(BₛCₜNᵤ) . . . (3)

In the above formula (3),

s, t and u are the atomic ratios of B, C and N, respectively, and the atomic ratios satisfy the following ranges:

0≤s≤0.15, 0≤t≤0.10, 0.80≤u≤1, and s+t+u=1.

In order to obtain by the above-mentioned multi-layering the same effect as that of the film of the above formula (1) in which Zr is homogeneously dissolved in solid in the film, the film thickness of each one layer of the film Q and the film R is required to be 1.0 nm or more. Each film thickness is preferably 2 nm or more, and more preferably 5 nm or more. In addition, the film thickness of each one layer of the film Q and the film R is required to be 50 nm or less, and it is preferably 30 nm or less, more preferably 20 nm or less, and still more preferably 10 nm or less. The hard film in which the film Q and the film R are laminated as described above is hereinafter sometimes referred to as the “lamination type hard film”.

The film thickness of one layer of the film Q and that of one layer of the film R are not necessarily required to be the same as each other, and may take any value as long as within the above-mentioned range. In the lamination type hard film of the present invention, either of the film Q and the film R may be arranged on a substrate side. Further, it may have such a film structure that the film Q or the film R present on the substrate side is also present on an outermost surface side, and may have various lamination structures depending on the purpose.

The total thickness of the hard film in which the above-mentioned film Q and film R are laminated is not limited in any way. However, in order to effectively exhibit the properties of the present invention, the total thickness of the hard film is preferably 0.5 μm or more. However, when the total thickness of the film is excessively increased, damage or separation of the film becomes liable to occur during cutting. Therefore, the total thickness is preferably 10 μm or less, more preferably 5 μm or less, and still more preferably 3 μm or less. Also in the case of the single layer satisfying the above formula (1), the film thickness is preferably 10 μm or less.

It is recommended that the number of times of lamination of the film Q and the film R is appropriately controlled so as to satisfy the preferred total thickness described above. In order to exhibit a function due to the film Q and the film R in a laminated state to the maximum, the number of times of lamination is preferably plural and 5 or more. From such a viewpoint, it is preferred to decrease the film thickness of each of the films Q and the films R to increase the number of times of lamination. The number of times of lamination used herein is a value when lamination of the single-layer film Q and the single-layer film R is defined as 1 for the number of times of lamination.

The present invention also includes a hard film-coated member in which the above-mentioned hard film is formed on a substrate. The hard film-coated members include, for example, cutting tools such as tips, drills and end mills, various dies for forging, press forming, extrusion forming, shearing, and the like, tools for plastic work such as blanking punches, and the like. In particular, they include tools for working metal materials, for example, tools for working used for general cutting or plastic work of iron-based materials. The present invention is most effective when applied to a cutting tool in which a material to be cut is pure titanium or a titanium alloy, or to a tool (jig) for plastic work in which a material to be worked is pure titanium or a titanium alloy and seizure on a sliding surface becomes a problem during the plastic work. The above-mentioned work may be either wet work or dry work, as long as it is such work that the adhesion or the seizure becomes a problem.

The kind of substrate used in the above-mentioned hard film-coated member is not particularly limited, and substrates described below are used. That is, examples thereof include WC-based cemented carbides such as WC—Co-based alloys, WC—TiC—Co-based alloys, WC—TiC—(TaC or NbC)—Co-based alloys, and WC—(TaC or NbC)—Co-based alloys; cermets such as TiC—Ni—Mo-based alloys and TiC—TiN—Ni—Mo-based alloys; high-speed steels such as SKH51 or SKD61 specified in JIS G 4403 (2006); ceramics; cubic boron nitride sintered bodies; diamond sintered bodies; silicon nitride sintered bodies; mixtures composed of aluminum oxide and titanium carbide; and the like.

When the hard film of the present invention is formed on the substrate, an intermediate layer of such as another metal, a nitride, a carbonitride, or a carbide may be formed between the substrate and the hard film, for the purpose of improving adhesiveness between the substrate and the hard film. The above-mentioned intermediate layers include, for example, TiN, CrN, TiAlN, CrAlN, TiCrAlN, and the like.

The hard film of the present invention can be formed on a surface of the substrate by using a known process such as a PVD process (physical vapor deposition process) or a CVD process (chemical vapor deposition process). As such a process, for example, an ion plating process such as an arc ion plating (AIP) process or a reactive PVD process such as a sputtering process is effective.

Methods for forming the hard films having the compositions of the above formulas (1) to (3) include the following method. For example, forming is performed by the AIP process or the sputtering process, by using an alloy target containing metal elements as components other than C and N constituting the above-mentioned film and further optionally containing B, as a target which is an evaporation source, and by using a nitrogen gas or a hydrocarbon gas such as methane or acetylene, as an atmosphere gas. An Ar gas may be contained in the above-mentioned atmosphere gas. Alternatively, deposition may be performed by using a target composed of a compound satisfying the compositions of the above formulas (1) to (3), that is, a target composed of a nitride, a carbonitride, a boronitride, or a carboboronitride. However, from the viewpoint of equipment cost or deposition rate, the method of using the alloy target is recommended.

In particular, when the lamination type hard film of the film Q represented by the above formula (2) and the film R represented by the above formula (3) is formed, the lamination type hard film may be formed, for example, by discharging Zr by the AIP process or the sputtering process, while forming a film composed of TiCrAlL(BCN) by the AIP process.

As an apparatus for forming the above-mentioned hard film, it is possible to use, for example, a PVD composite device equipped with both of an arc evaporation source and a sputtering evaporation source, which is illustrated in FIG. 1 of JP-A-2008-024976.

The temperature of the substrate during the deposition may be appropriately selected depending on the kind of substrate. From the viewpoint of securing the adhesiveness between the substrate and the hard film, it can be adjusted to 300° C. or higher, and further to 400° C. or higher. In addition, from the viewpoint of deformation prevention and the like of the substrate, the temperature of the substrate can be adjusted to 700° C. or lower, and further to 600° C. or lower.

Further, as other deposition conditions, the total pressure of the atmosphere gas: 0.5 Pa or more and 4 Pa or less, the arc current: 100 to 200 A, the bias voltage applied to the substrate: −30 to −200 V, the electric power inputted into the sputtering evaporation source: 0.1 to 3 kW, and the like can be adopted.

### EXAMPLES

The present invention will be more specifically described below with reference to Examples. However, the present invention should not be construed as being limited by the following Examples, and can, of course, be carried out with appropriate changes within the scope adaptable to the gist described above and below. All of these are included in the technical scope of the present invention.

### Example 1

Films having the compositions shown in Table 1 were formed by using a PVD composite device having a plurality of arc evaporation sources and a plurality of sputtering evaporation sources and capable of performing both the AIP process and the sputtering process. The hard film of the present invention can be deposited by both the AIP process and the sputtering process as described above. In the following, however, the film was formed by the AIP process. As a substrate, a mirrored cemented carbide test piece of 13 mm square x 4 mm thick was prepared for hardness investigation, and an insert (CNMG432, cemented carbide) was prepared for a cutting test. Then, deposition was performed on these substrates at the same time. In detail, these substrates were introduced into the above-mentioned device, and then, after exhaustion to 5 ×10⁻³ Pa, the substrates were heated to 500° C. and subjected to etching with Ar ions for 5 minutes. Thereafter, only nitrogen or a mixed gas of nitrogen and a methane gas was introduced up to 4 Pa, and the above-mentioned films of about 3 μm were formed under the condition of an arc current of 150 A and a bias voltage applied to the substrates of −50 V to obtain a sample for the hardness investigation and a sample for the cutting test.

In the above-mentioned deposition, there was used an alloy target containing metal elements as components other than C and N constituting each film, and further containing B depending on the composition. As the alloy target, there was used a powder metallurgical target obtained by mixing these elements so as to have the desired composition and performing solidification and baking by a HIP process.

In addition, as comparative examples, samples in which a TiAlN film, a TiCrAlN film, a TiCrAlSiN film, and an AlCrN film were each formed were also prepared.

By using the sample for the hardness investigation and the sample for the cutting test thus obtained, the hardness investigation and the cutting test were performed as follows.

### Hardness Investigation

By using the above-mentioned sample for the hardness investigation, the Vickers hardness was measured under the condition of a load of 1 N.

### Cutting Test

It is said that the progress of wear in the case of cutting the titanium-based metal is mainly adhesion wear. In this Example, therefore, the adhesion resistance was evaluated by the cutting life as shown below. That is, by using the above-mentioned sample for the cutting test, the cutting test was performed under the following conditions, and the adhesion resistance was evaluated at the cutting length at which the maximum part of the flank wear reached 300 μm, as shown below. The cutting length at which the maximum part of the flank wear reaches 300 μm is hereinafter simply referred to as the “cutting life”.

### Cutting Test Conditions

Tool: CNMG432, material; K313

Material to be cut: Ti-6A1-4V

Speed: 45 m/min

Feed: 0.15 mm/min

DOC (Depth Of Cut): 2 mm

Lubrication: Wet

Evaluation: Cutting length at which the maximum part of the flank wear reaches 300 μm

When the above-mentioned Vickers hardness was higher and the cutting life was longer, the adhesion resistance and the wear resistance were evaluated to be more excellent, and the tool life was evaluated to be longer. The results thereof are shown in Table 1.

TABLE 1

| | | | | | | | | | | | Cutting |
|---|---|---|---|---|---|---|---|---|---|---|---|
| | Composition of Film (Atomic Ratio) | | | | | | | | | Hardness | Life |
| No. | Ti | Cr | Al | Zr | Si | Y | B | C | N | HV | (m) |
| 1 | 0.19 | 0.20 | 0.60 | 0.01 | 0 | 0 | 0 | 0 | 1 | 2500 | 1500 |
| 2 | 0.15 | 0.20 | 0.60 | 0.05 | 0 | 0 | 0 | 0 | 1 | 2800 | 3500 |
| 3 | 0.10 | 0.20 | 0.60 | 0.10 | 0 | 0 | 0 | 0 | 1 | 3000 | 4000 |
| 4 | 0.10 | 0.15 | 0.60 | 0.15 | 0 | 0 | 0 | 0 | 1 | 3000 | 3000 |
| 5 | 0.10 | 0.10 | 0.60 | 0.20 | 0 | 0 | 0 | 0 | 1 | 2900 | 3000 |
| 6 | 0.05 | 0.05 | 0.60 | 0.30 | 0 | 0 | 0 | 0 | 1 | 2600 | 2200 |
| 7 | 0 | 0.30 | 0.63 | 0.07 | 0 | 0 | 0 | 0 | 1 | 2800 | 3200 |
| 8 | 0.10 | 0.23 | 0.60 | 0.07 | 0 | 0 | 0 | 0 | 1 | 3000 | 4000 |
| 9 | 0.30 | 0.10 | 0.53 | 0.07 | 0 | 0 | 0 | 0 | 1 | 2700 | 3300 |
| 10 | 0.40 | 0.10 | 0.43 | 0.07 | 0 | 0 | 0 | 0 | 1 | 2400 | 1500 |
| 11 | 0.20 | 0 | 0.73 | 0.07 | 0 | 0 | 0 | 0 | 1 | 2200 | 1000 |
| 12 | 0.20 | 0.10 | 0.63 | 0.07 | 0 | 0 | 0 | 0 | 1 | 2800 | 3000 |
| 13 | 0.20 | 0.20 | 0.53 | 0.07 | 0 | 0 | 0 | 0 | 1 | 3000 | 3600 |
| 14 | 0.10 | 0.30 | 0.53 | 0.07 | 0 | 0 | 0 | 0 | 1 | 2700 | 3200 |
| 15 | 0.10 | 0.40 | 0.43 | 0.07 | 0 | 0 | 0 | 0 | 1 | 2500 | 1500 |
| 16 | 0.365 | 0.365 | 0.20 | 0.07 | 0 | 0 | 0 | 0 | 1 | 2200 | 1300 |
| 17 | 0.265 | 0.265 | 0.40 | 0.07 | 0 | 0 | 0 | 0 | 1 | 2600 | 2600 |
| 18 | 0.215 | 0.215 | 0.50 | 0.07 | 0 | 0 | 0 | 0 | 1 | 2800 | 3100 |
| 19 | 0.165 | 0.165 | 0.60 | 0.07 | 0 | 0 | 0 | 0 | 1 | 3000 | 3700 |
| 20 | 0.115 | 0.115 | 0.70 | 0.07 | 0 | 0 | 0 | 0 | 1 | 2700 | 2800 |
| 21 | 0.065 | 0.065 | 0.80 | 0.07 | 0 | 0 | 0 | 0 | 1 | 2300 | 1900 |
| 22 | 0.165 | 0.165 | 0.60 | 0.07 | 0.03 | 0 | 0 | 0 | 1 | 3200 | 4000 |
| 23 | 0.165 | 0.165 | 0.55 | 0.07 | 0.05 | 0 | 0 | 0 | 1 | 3300 | 4100 |
| 24 | 0.165 | 0.165 | 0.50 | 0.07 | 0.10 | 0 | 0 | 0 | 1 | 2900 | 3500 |
| 25 | 0.165 | 0.165 | 0.45 | 0.07 | 0.15 | 0 | 0 | 0 | 1 | 2200 | 1700 |
| 26 | 0.165 | 0.165 | 0.57 | 0.07 | 0.03 | 0.02 | 0 | 0 | 1 | 3300 | 4000 |
| 27 | 0.165 | 0.165 | 0.60 | 0.07 | 0 | 0.05 | 0 | 0 | 1 | 3300 | 3900 |
| 28 | 0.165 | 0.165 | 0.60 | 0.07 | 0 | 0 | 0.10 | 0 | 0.90 | 3300 | 3700 |
| 29 | 0.165 | 0.165 | 0.60 | 0.07 | 0 | 0 | 0.20 | 0 | 0.80 | 2400 | 2000 |
| 30 | 0.165 | 0.165 | 0.60 | 0.07 | 0 | 0 | 0 | 0.05 | 0.95 | 3000 | 3600 |
| 31 | 0.165 | 0.165 | 0.60 | 0.07 | 0 | 0 | 0.03 | 0.07 | 0.90 | 3100 | 3600 |
| 32 | 0.165 | 0.165 | 0.60 | 0.07 | 0 | 0 | 0 | 0.15 | 0.85 | 2400 | 1800 |

| | | | |
|---|---|---|---|
| 33 | Ti0.5Al0.5N | 2300 | 1000 |
| 34 | (Ti0.2Cr0.2Al0.6)N | 2500 | 1500 |
| 35 | (Ti0.2Cr0.2Al0.57Si0.03)N | 2900 | 2000 |
| 36 | (Al0.6Cr0.4)N | 2500 | 1800 |

The following is found from Table 1. Nos. 1 to 6 are examples in which the influence of the Zr amount d was investigated. Of these examples, in Nos. 2 to 5, the atomic ratios of Zr and the other elements were within the specified ranges, the hardness was high, and the cutting life was also increased. On the other hand, when the Zr amount d was insufficient as No. 1, the cutting life was shortened. In addition, when the Zr amount d was excessive as No. 6, the cutting life was also shortened.

Nos. 7 to 10 are examples in which the influence of the Ti amount a was investigated. Of these examples, in Nos. 7 to 9, the atomic ratios of Ti and the other elements were within the specified ranges, the hardness was high, and the cutting life was also prolonged. On the other hand, in No. 10, the Ti amount a was excessive, so that the cutting life was shortened.

Nos. 11 to 15 are examples in which the influence of the Cr amount b was investigated. Of these examples, in Nos. 12 to 14, the atomic ratios of Cr and the other elements were within the specified ranges, the hardness was high, and the cutting life was also increased. On the other hand, in No. 11, Cr was not contained, and the Al amount c was excessive. Therefore, the hardness was low, and the cutting life was also considerably shortened. In addition, in No. 15, the Cr amount b was excessive, so that the cutting life was shortened.

Nos. 16 to 21 are examples in which the influence of the Al amount c was investigated. Of these examples, in Nos. 17 to 20, the atomic ratios of Al and the other elements were within the specified ranges, the hardness was high, and the cutting life was also prolonged. On the other hand, in No. 16, Al was insufficient, and Ti and Cr were excessively contained. Therefore, the hardness was low, and the cutting life was also shortened. In addition, in No. 21, the Al amount c was excessive, so that the hardness was low and the cutting life was short.

Nos. 22 to 27 are examples in which the influence of the content e of L, that is to say, Si and Y, was investigated. Of these examples, in Nos. 22 to 24, 26 and 27, the atomic ratios of L and the other elements were within the specified ranges, the hardness was high, and the cutting life was also increased. When these examples containing L in specified amounts are compared with, for example, No. 19, it is found that the cutting life is sufficiently prolonged by adding L in small amounts. On the other hand, in No. 25, the L amount e exceeded the upper limit of the specified range, so that the hardness was low and the cutting life was also shortened.

Nos. 28 and 29 are examples in which the influence of the B amount x was investigated. In No. 28, the atomic ratios of B and the other elements were within the specified ranges, the hardness was high, and the cutting life was also prolonged. In contrast, in No. 29, B was excessively contained, so that the hardness was low and the cutting life was shortened.

Nos. 30 to 32 are examples in which the influence of the C amount y was investigated. In Nos. 30 and 31, the atomic ratios of C and the other elements were within the specified ranges, the hardness was high, and the cutting life was also prolonged. On the other hand, in No. 32, the C amount y was excessive, so that the hardness was low and the cutting life was shortened.

Nos. 33 to 36 are examples showing the results of forming the films that have been conventionally used. In all of these examples, particularly, the cutting life was short.

### Example 2

Lamination type hard films in which TiCrAlN films as the films Q and ZrN films as the films R were alternately laminated as shown in Table 2 were formed by the AIP process, by using particularly the AIP evaporation sources of the same device as in Example 1. The details thereof are as follows. The same substrates as in Example 1 were prepared, and deposition was performed in the same manner as in Example 1 except for alternately laminating the films Q having the composition and film thickness shown in Table 2 and the films R having the composition and film thickness shown in Table 2 to form a laminated film having a total thickness of about 3 μm. The respective film thicknesses of the films Q and the films R in Table 2 were varied by changing lamination cycles. A (Ti, Cr, Al) target containing the components other than N was used for formation of the above-mentioned films Q, and a Zr target was used for formation of the above-mentioned films R.

By using a sample for the hardness investigation and a sample for the cutting test thus obtained, the hardness investigation and the cutting test were performed in the same manner as in Example 1. The results thereof are shown in Table 2.

TABLE 2

| | Film Q | | Film R | | | |
|---|---|---|---|---|---|---|
| | | Film | | Film | | Cutting |
| | | Thickness | | Thickness | Hardness | Life |
| No. | Composition | (nm) | Composition | (nm) | HV | (m) |
| 1 | (Ti0.20Cr0.20Al0.60)N | 0.5 | ZrN | 0.5 | 2500 | 1700 |
| 2 | | 5 | | 5 | 3000 | 3100 |
| 3 | | 10 | | 10 | 3100 | 3200 |
| 4 | | 20 | | 20 | 2900 | 3000 |
| 5 | | 50 | | 50 | 2900 | 3000 |
| 6 | | 100 | | 100 | 2200 | 1800 |

The following is found from Table 2. Nos. 1 to 6 are examples in which the compositions and the total thickness of the films Q and the films R were the same, and the film thickness of one layer of each film was changed. Of these examples, in Nos. 2 to 5, the compositions and the film thicknesses of the films Q and the films R satisfied the ranges specified in the present invention, so that the hardness was high and the cutting life was also long, resulting in obtaining excellent adhesion resistance and wear resistance. In contrast, in No. 1, both the film thicknesses of the films Q and the films R were thin, so that the hardness was low and the cutting life was shortened. In No. 6, both the film thicknesses of the films Q and the films R exceeded the specified ranges, so that the hardness was low and the cutting life was also short, resulting in inferior adhesion resistance and wear resistance.

While the present invention has been described in detail and with reference to specific embodiments thereof, it will be apparent to one skilled in the art that various changes and modifications can be made therein without departing from the spirit and scope of the present invention.

The present application is based on a Japanese patent application (No. 2015-097299) filed on May 12, 2015, the content thereof being incorporated herein by reference.

### INDUSTRIAL APPLICABILITY

The present invention is useful for a cutting tool used for cutting of pure titanium or a titanium alloy or a tool for plastic work used for plastically working pure titanium or a titanium alloy.

1. A hard film to be formed on a substrate, the hard film comprising a composition represented by formula (1):
TiₐCr_{b}Al_{c}Zr_{d}Lₑ(BₓC_{y}N_{z}) (1),
wherein:
L is one or more of Si and Y;
a, b, c, d, e, x, y, and z are atomic ratios of Ti, Cr, Al, Zr, L, B, C, and N, respectively; and
the atomic ratios satisfy the following ranges:
0≤a≤0.30,
0.10≤b 0.30,
0.40≤c≤0.70,
0.03≤d≤0.20,
0≤e≤0.10,
0≤x≤0.15,
0≤y≤0.10,
0.80≤z≤1.
a+b+c+d+e=1, and
x+y+z=1.

2. A hard film to be formed on a substrate, the hard film comprising:
at least one film Q comprising a composition represented by formula (2) and having a film thickness of 1.0 nm or more and 50 nm or less:
TiₐCr_{b}Al_{c}L_{c}(BₓC_{y}N_{z}) (2); and
at least one film R comprising a composition represented by formula (3) and having a film thickness of 1.0 nm or more and 50 nm or less:
Zr(BₛCₜNᵤ) (3),
wherein:
the at least one film Q and the at least one film R are alternately laminated;
L is one or more of Si and Y;
a, b, c, e, x, y, and z are atomic ratios of Ti, Cr, Al, L, B, C, and N, respectively;
the atomic ratios of formula (2) satisfy the following ranges:
0≤a≤0.30,
0.10≤b 0.30,
0.40≤c≤0.70,
0≤e≤0.10,
0≤x≤0.15,
0≤y≤0.10,
0.80≤z≤1,
a+b+c+e=1, and
x+y+z=1;
s, t and u are atomic ratios of B, C and N, respectively; and
the atomic ratios of formula (3) satisfy the following ranges:
0≤s≤0.15,
0≤t≤0.10,
0.80≤u≤1, and
s+t+u=1.

3. A hard film-coated member, comprising a substrate and the hard film of claim 1, the hard film being formed on the substrate.

4. The hard film-coated member according to claim 3, which is a cutting tool adapted to function as a cutting tool for cutting a pure titanium or a titanium alloy.

5. The hard film-coated member according to claim 3, which is a tool for plastic work adapted to function as a tool for plastically working a pure titanium or a titanium alloy.

6. A hard film-coated member, comprising a substrate and the hard film of claim 2, the hard film being formed on the substrate.

7. The hard film-coated member according to claim 6, which is a cutting tool adapted to function as a cutting tool for cutting a pure titanium or a titanium alloy.

8. The hard film-coated member according to claim 6, which is a tool for plastic work adapted to function as a tool for plastically working a pure titanium or a titanium alloy.
